(19) United States
(12) Patent Application Publication
(10) Pub. No.: US 2024/0250498 A1
(43) Pub. Date: Jul. 25, 2024

(54) LIGHT-EMITTING DEVICE

(71) Applicant: NICHIA CORPORATION, Anan-shi (JP)

(72) Inventors: Tadaaki MIYATA, Yokohama-shi (JP); Kazuma KOZURU, Anan-shi (JP)

(73) Assignee: NICHIA CORPORATION, Anan-shi (JP)

(21) Appl. No.: 18/417,059

(22) Filed: Jan. 19, 2024

(30) Foreign Application Priority Data
Jan. 25, 2023 (JP) 2023-009224
Aug. 31, 2023 (JP) 2023-141543

(51) Int. Cl. H01S 5/024; H01S 5/02315; H01S 5/0232

(52) U.S. Cl. CPC H01S 5/02476; H01S 5/02315; H01S 5/0232; H01S 5/02469

(57) ABSTRACT

A light-emitting device includes: a heat dissipation member having a mounting surface; a frame body fixed to the heat dissipation member and having an upper surface; a submount supported by the mounting surface and having an upper surface and a lower surface; and a semiconductor laser element supported by the upper surface of the submount. The lower surface of the submount includes a first region bonded to the mounting surface and a second region facing the upper surface of the frame body and not bonded to the upper surface of the frame body.

### CROSS-REFERENCE TO RELATED APPLICATIONS

This application claims priority to Japanese Patent Application No. 2023-009224, filed on Jan. 25, 2023, and Japanese Patent Application No. 2023-141543, filed on Aug. 31, 2023. The disclosures of these applications are hereby incorporated by reference in their entireties.

### BACKGROUND

The present disclosure relates to a light-emitting device.

Light-emitting devices including a semiconductor laser element are used for devices, such as a projector, a lighting device, and a processing machine. Because such light-emitting devices expand due to heat generated from the semiconductor laser element during driving, the material and the size thereof are determined such that the difference in thermal expansion coefficient are reduced (for example, see JP 2009-535806 T).

### SUMMARY

There has been a demand for a light-emitting device in which a load experienced between the components can be reduced even when components in the light-emitting device expand due to heat generated from a semiconductor laser element during driving.

A light-emitting device according to one embodiment of the present disclosure includes a heat dissipation member having a mounting surface, a frame body fixed to the heat dissipation member and having an upper surface, a submount supported by the mounting surface and having an upper surface and a lower surface, and a semiconductor laser element supported by the upper surface of the submount. The lower surface of the submount includes a first region bonded to the mounting surface and a second region facing the upper surface of the frame body and not bonded to the upper surface of the frame body.

A light-emitting device according to an embodiment of the present disclosure includes a heat dissipation member having a first upper surface and a second upper surface located below the first upper surface, a frame body having a first lower surface and a second lower surface that is located above the first lower surface and is bonded to the second upper surface of the heat dissipation member, a submount supported by the first upper surface and having an upper surface and a lower surface, and a semiconductor laser element supported by the upper surface of the submount. The lower surface of the submount includes a first region bonded to the first upper surface and a second region not bonded to the first upper surface.

An embodiment of the present disclosure can implement the light-emitting device that allows, even when the components in the light-emitting device expand due to heat generated from the semiconductor laser element during driving, a load experienced between the components to be reduced.

### BRIEF DESCRIPTION OF DRAWINGS

FIG. 1A is a perspective view schematically illustrating a configuration of a light-emitting device according to an exemplary first embodiment of the present disclosure.

FIG. 1B is a schematic exploded perspective view of the light-emitting device illustrated in FIG. 1A.

FIG. 1C is a schematic exploded perspective view of the lowermost part among the four separated parts illustrated in FIG. 1B.

FIG. 1D is another schematic exploded perspective view of the lowermost part among the four separated parts illustrated in FIG. 1B.

FIG. 1E is a schematic perspective view when a frame body in a configuration illustrated in FIG. 1D is viewed from below.

FIG. 1F is a schematic cross-sectional view parallel to a YZ plane of the light-emitting device illustrated in FIG. 1A.

FIG. 1G is a schematic cross-sectional view parallel to an XY plane of the light-emitting device illustrated in FIG. 1A.

FIG. 2A is a cross-sectional view parallel to the XY plane, schematically illustrating a configuration of a modified example of the light-emitting device according to the first embodiment of the present embodiment.

FIG. 2B is a cross-sectional view parallel to the YZ plane, schematically illustrating the configuration of the modified example of the light-emitting device according to the first embodiment of the present embodiment.

FIG. 3A is a perspective view schematically illustrating a configuration of a light-emitting device according to an exemplary second embodiment of the present disclosure.

FIG. 3B is a schematic exploded perspective view of the light-emitting device illustrated in FIG. 3A.

FIG. 3C is a schematic cross-sectional view parallel to a YZ plane of the light-emitting device illustrated in FIG. 3A.

### DETAILED DESCRIPTION

Light-emitting devices according to certain embodiments of the present disclosure will be described below with reference to the drawings. Parts designated with the same reference numerals appearing in multiple drawings indicate identical or equivalent parts.

The embodiment described below is exemplified to embody a technical idea of the present invention, and the present invention is not limited to the following. The descriptions of dimensions, materials, shapes, relative arrangements, and the like of components are not intended to limit the scope of the present invention thereto but intended to be illustrative. The size and positional relationship of members illustrated in the drawings may be exaggerated to facilitate understanding.

In the present description or the scope of claims, the term “polygon,” (which includes, e.g., triangles or quadrangles) includes shapes in which the corners of the polygons are rounded, chamfered, beveled, or coved. Not only a shape with modification at its corner (an end of a side), but also a shape with modification at an intermediate portion of a side thereof is referred to as a polygon. In other words, a polygon-based shape with partial modification is included in the interpretation of “polygon” described in the present description and the scope of claims.

### First Embodiment

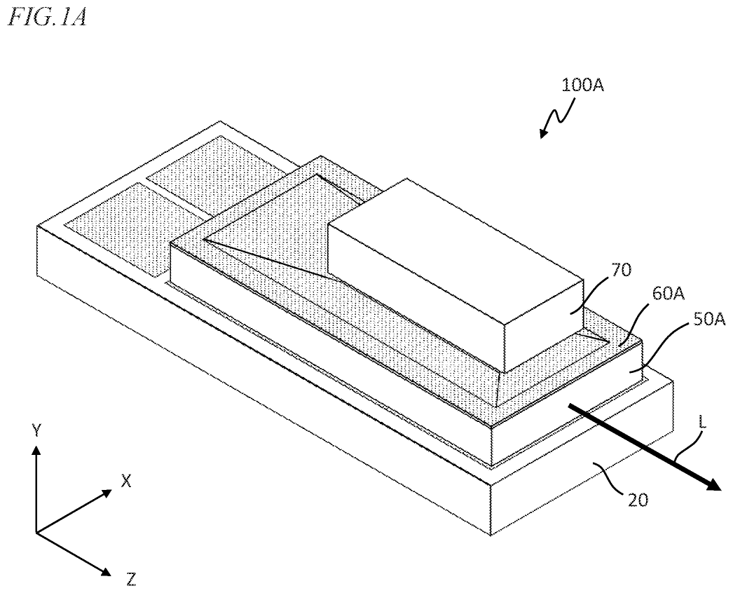

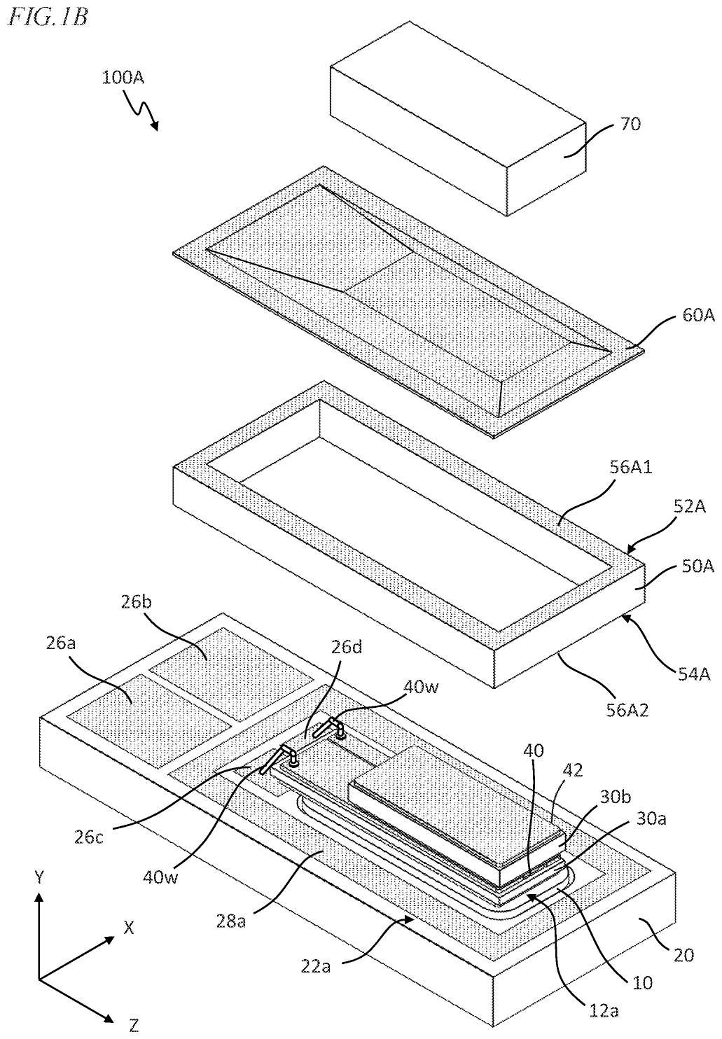

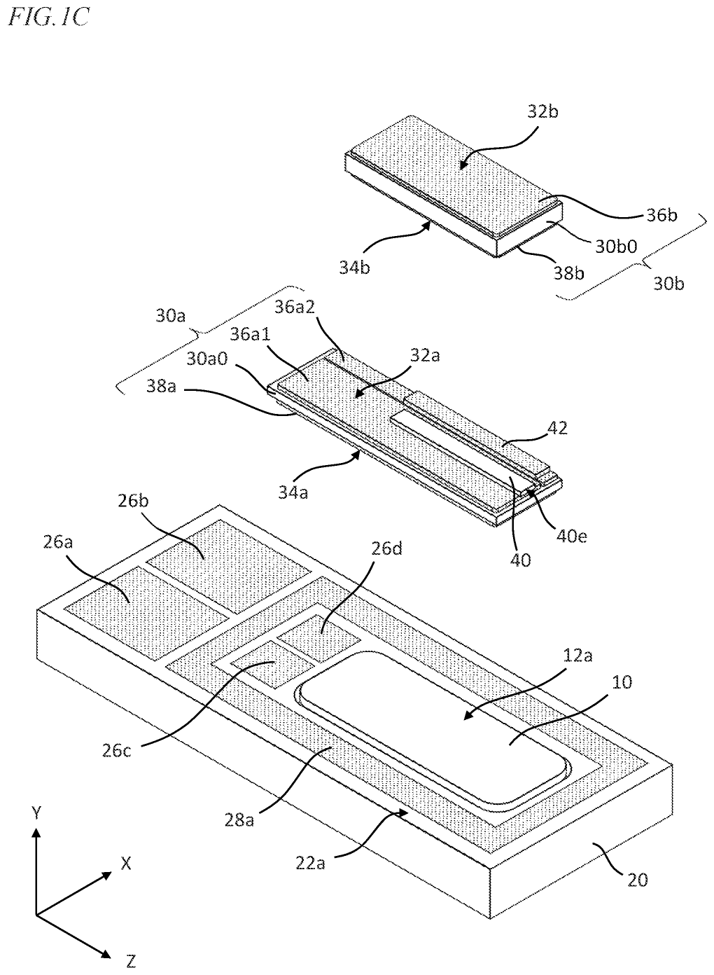

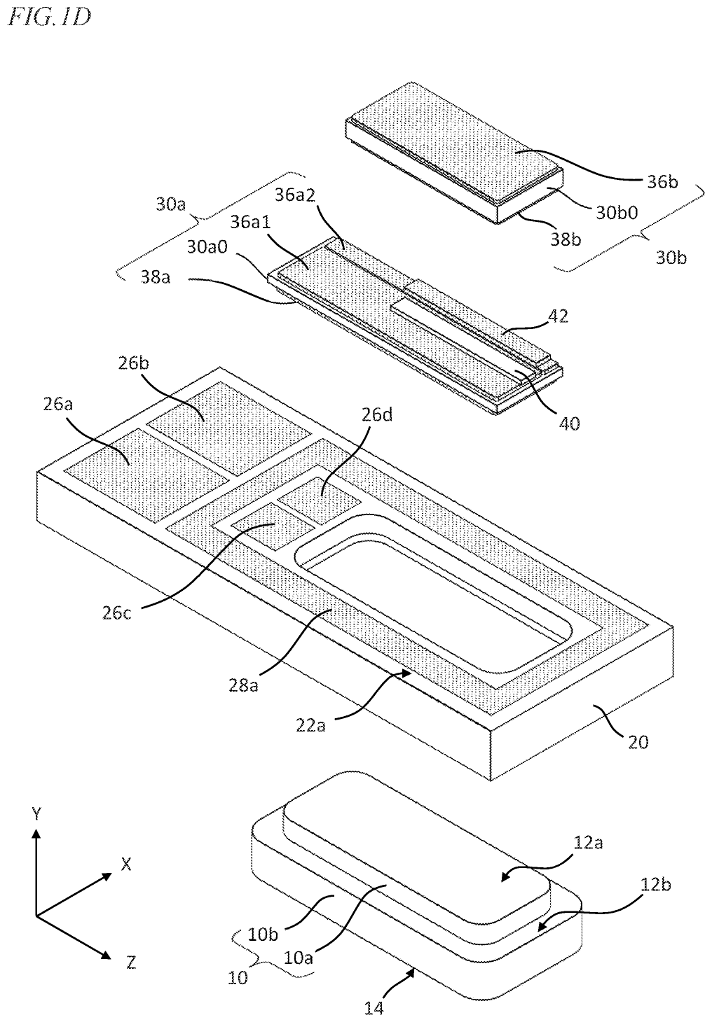

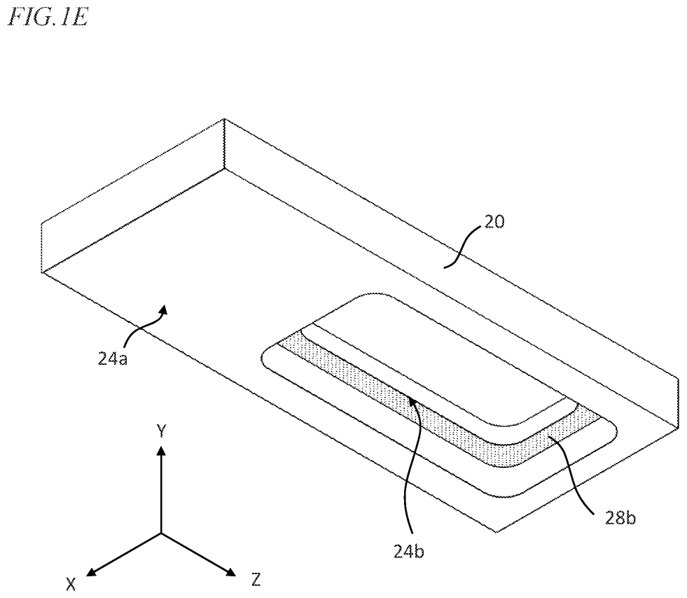

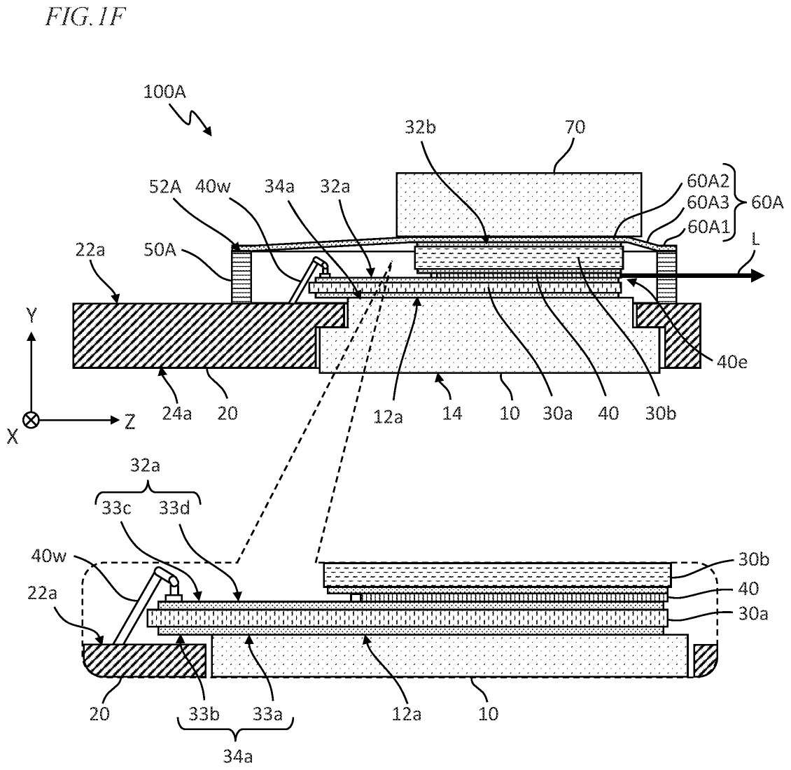

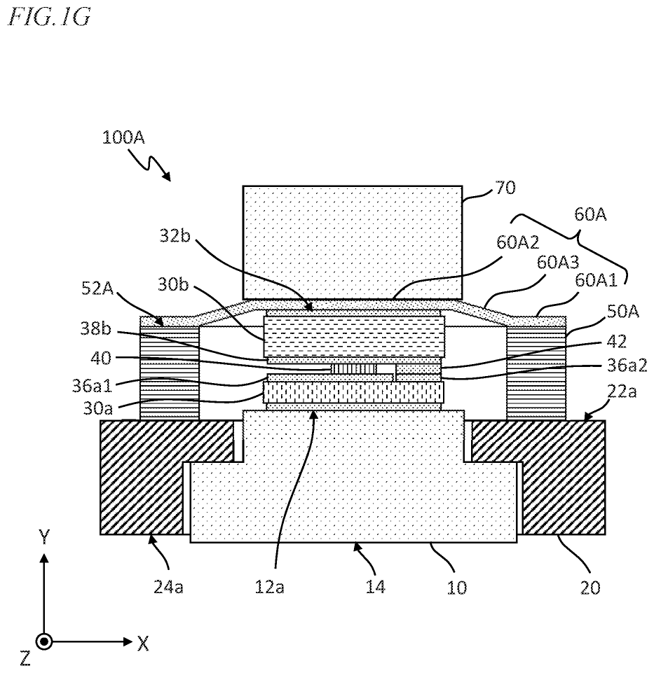

First, a configuration example of the light-emitting device according to the first embodiment of the present disclosure will be described with reference to FIGS. 1A and 1B. An X-axis, a Y-axis, and a Z-axis that are orthogonal to one another in the drawings are schematically illustrated for reference. The direction of an arrow on the X-axis is referred to as a +X direction, and a direction opposite thereto is referred to as a −X direction. When the ±X directions are not distinguished, the ±X directions are simply referred to as X directions. The same applies to a Y direction and a Z direction. For ease of understanding of the description, in the present description, the +Y direction is referred to as “upward,” the −Y direction is referred to as “downward,” the +Z direction is referred to as “forward,” and the −Z direction is referred to as “rearward.” This does not limit the orientation of the light-emitting device during use, and the light-emitting device may be oriented in any appropriate direction.

FIG. 1A is a perspective view schematically illustrating the configuration of the light-emitting device according to the exemplary first embodiment of the present disclosure. A light-emitting devices 100A illustrated in FIG. 1A emits laser light L forward. The arrow illustrated in FIG. 1A indicates the traveling direction of the laser light L. The laser light L is emitted from a semiconductor laser element housed inside the light-emitting device 100A. FIG. 1B is an exploded perspective view of the light-emitting device 100A illustrated in FIG. 1A. As illustrated in FIG. 1B, the light-emitting device 100A includes a heat dissipation member 10, a frame body 20 fixed to the heat dissipation member 10, a first submount 30a, a second submount 30b, a semiconductor laser element 40 and a relay member 42 that are located between the two submounts, and two conductive members 40w electrically connected to the semiconductor laser element 40. The heat dissipation member 10 has a first upper surface 12a that supports the first submount 30a. The light-emitting device 100A further includes a sidewall 50A surrounding the first submount 30a, the second submount 30b, and the semiconductor laser element 40, a sealing member 60A sealing a space accommodating the semiconductor laser element 40, and a heat dissipation block 70 disposed on the sealing member 60A. The light-emitting device 100A may further include a protective element, such as a Zener diode, and/or a temperature measuring element for measuring an internal temperature, such as a thermistor. In the present description, the first submount 30a is also simply referred to as a “submount” and the second submount 30b is also referred to as “additional submount.”

FIG. 1C is an exploded perspective view of the lowermost part among the four separated parts illustrated in FIG. 1B. The first submount 30a has an upper surface 32a and a lower surface 34a. The upper surface 32a of the first submount 30a supports the semiconductor laser element 40 and the relay member 42. The second submount 30b has an upper surface 32b and a lower surface 34b similar to the first submount 30a.

FIG. 1D is another exploded perspective view of the lowermost part among the four separated parts illustrated in FIG. 1B. FIG. 1E is a perspective view when the frame body 20 in a configuration illustrated in FIG. 1D is viewed from below. FIG. 1F is a cross-sectional view parallel to the YZ plane of the light-emitting device illustrated in FIG. 1A. In the region enclosed by the broken line illustrated in FIG. 1F, the heat dissipation member 10, the first submount 30a, and their peripheral configurations are illustrated in an enlarged manner. FIG. 1G is a cross-sectional view parallel to the XY plane of the light-emitting device illustrated in FIG. 1A.

As will be described in detail later, as illustrated in FIG. 1F, in the light-emitting device 100A according to the first embodiment, the lower surface 34a of the first submount 30a includes a first region 33a bonded to the first upper surface 12a and a second region 33b that faces an upper surface 22a of the frame body 20 and that is not bonded to the upper surface 22a of the frame body 20. Presence of the second region 33b allows for widening the upper surface 32a of the first submount 30a. Therefore, a region where the semiconductor laser element 40 is provided can be wider.

When the heat dissipation member 10 expands due to heat generated from the semiconductor laser element 40, the expansion may cause the heat dissipation member 10 and the frame body 20 to shift in position. Even in this case, with the second region 33b not bonded to the upper surface 22a of the frame body 20, the load experienced on the first submount 30a and the frame body 20 can be reduced.

Therefore, according to the first embodiment, the light-emitting device can be obtained in which a load experienced between the components can be reduced even when the components in the light-emitting device expand due to the heat generated from the semiconductor laser element during driving.

Components of the light-emitting device 100A will be described below in detail.

### Heat Dissipation Member 10

As illustrated in FIG. 1D, the heat dissipation member 10 has a first flat plate part 10a and a second flat plate part 10b wider than the first flat plate part 10a in a top view as seen along the +Y direction. The first flat plate part 10a is a part that protrudes from the second flat plate part 10b in the +Y direction. The first upper surface 12a of the heat dissipation member 10 corresponds to the upper surface of the first flat plate part 10a. In the present description, the first upper surface 12a is also referred to as a “mounting surface.” The direction normal to the first upper surface 12a is the +Y direction. The direction normal to the surface means a direction perpendicular to the surface and extending away from an object having the surface. The heat dissipation member 10 has a second upper surface 12b in addition to the first upper surface 12a. The second upper surface 12b corresponds to a region in the upper surface of the second flat plate part 10b that does not overlap with the first upper surface 12a in the top view as seen along the normal direction of the first upper surface 12a. The second upper surface 12b surrounds the first upper surface 12a in the top view. The second upper surface 12b is located below the first upper surface 12a. The heat dissipation member 10 further has a lower surface 14 corresponding to the lower surface of the second flat plate part 10b.

As illustrated in FIGS. 1F and 1G, in the XZ plane, there are clearances between the heat dissipation member 10 and the frame body 20, more specifically, between the first flat plate part 10a and the frame body 20 and between the second flat plate part 10b and the frame body 20. With the clearances, even when the heat dissipation member 10 expands due to the heat generated from the semiconductor laser element 40 during driving, the possibility that the frame body 20 is damaged can be reduced.

In the example illustrated in FIG. 1D, the first upper surface 12a has an approximately rectangular shape, the second upper surface 12b has an approximately rectangular annular shape, and the lower surface 14 has an approximately rectangular shape. The lower surface 14 of the heat dissipation member 10 is bonded to a support member supporting the light-emitting device 100A via an inorganic bonding member, such as a solder material. For example, the support member may be a heat sink for reducing an excessive temperature rise of the light-emitting device 100A or may be a heat spreader for transferring the heat generated from the light-emitting device 100A to a separately prepared heat sink.

The thermal conductivity of the heat dissipation member 10 may be, for example, in a range of 10 W/m·K to 2000 W/m·K. The heat dissipation member 10 having such thermal conductivity allows the heat generated from the semiconductor laser element 40 during driving to be effectively transferred to the outside of the light-emitting device 100A via the heat dissipation member 10.

When the heat dissipation member 10 and the frame body 20 are made of materials different from one another, the thermal expansion coefficient of the heat dissipation member 10 may differ from the thermal expansion coefficient of the frame body 20. The absolute value of the difference between the thermal expansion coefficient of the heat dissipation member 10 and the thermal expansion coefficient of the frame body 20 may be, for example, in a range of 1.0×10⁻⁶K to 5.0×10⁻⁵K⁻¹. In a case in which there is such a difference between their thermal expansion coefficients, when the dimensions of the heat dissipation member 10 in the X direction and the Z direction are large, the heat dissipation member 10 expands due to the heat generated from the semiconductor laser element 40 during driving, which may result in disconnection between the heat dissipation member 10 and the frame body 20. In a case in which the heat dissipation member 10 is located inside a square having one side of 7 mm in the top view, the dimensions of the heat dissipation member 10 in the X direction and the Z direction are not so large, allowing for reducing the possibility that the heat dissipation member 10 and the frame body 20 are disconnected from each other due to the thermal expansion of the heat dissipation member 10.

The heat dissipation member 10 may be made of, for example, at least one metal material selected from the group consisting of Cu, Al, and Ag. The heat dissipation member 10 may have the maximum dimension in the X direction in a range of, for example, 1 mm to 10 mm, the maximum dimension in the Y direction in a range of, for example, 1 mm to 20 mm, and the maximum dimension in the Z direction in a range of, for example, 0.1 mm to 1 mm.

### Frame Body 20

The frame body 20 fixed to the heat dissipation member 10 surrounds the heat dissipation member 10 as illustrated in FIG. 1C. The frame body 20 has the upper surface 22a located outside the first upper surface 12a of the heat dissipation member 10 in the top view. The upper surface 22a of the frame body 20 supports the sidewall 50A. In the example illustrated in FIG. 1C, the first upper surface 12a of the heat dissipation member 10 is located above the upper surface 22a of the frame body 20. The effect obtained by the relationship between the heights of these two upper surfaces will be described below.

Other than the example illustrated in FIG. 1C, the first upper surface 12a of the heat dissipation member 10 and the upper surface 22a of the frame body 20 may be in the same plane. Alternatively, the first upper surface 12a of the heat dissipation member 10 may be located lower than the upper surface 22a of the frame body 20 as long as the first submount 30a and the heat dissipation member 10 can be bonded together via an inorganic bonding member, such as a solder material.

The upper surface 22a includes a first conductive region 26a and a second conductive region 26b electrically insulated from each other, and a third conductive region 26c and a fourth conductive region 26d electrically insulated from each other. Each of the conductive regions 26a to 26d has an approximately rectangular shape, but may have other shape. The shape of each of the conductive regions 26a to 26d may be, for example, a circular shape or an elliptical shape. The first conductive region 26a and the third conductive region 26c are electrically connected to each other via internal writing. The same applies to the second conductive region 26b and the fourth conductive region 26d. As illustrated in FIG. 1B, each of the third conductive region 26c and the fourth conductive region 26d is electrically connected to the semiconductor laser element 40 via a corresponding one of the conductive members 40w. By applying a voltage between the first conductive region 26a and the second conductive region 26b, power can be supplied to the semiconductor laser element 40.

A first bonding region 28a is further provided on the upper surface 22a. As illustrated in FIG. 1C, the first bonding region 28a surrounds the third conductive region 26c, the fourth conductive region 26d, and the first upper surface 12a of the heat dissipation member 10 in the top view. With the first bonding region 28a, when the frame body 20 and the sidewall 50A illustrated in FIG. 1B are bonded together via an inorganic bonding member such as a solder material, the bonding strength can be improved.

As illustrated in FIG. 1E, the frame body 20 further has a first lower surface 24a and a second lower surface 24b. The second lower surface 24b is located above the first lower surface 24a, and surrounded by the first lower surface 24a in a bottom view as seen along the −Y direction. The second lower surface 24b has a substantially rectangular annular shape. A portion or an entirety of the second flat plate part 10b in the heat dissipation member 10 illustrated in FIG. 1D is accommodated in a space surrounded by the step between the first lower surface 24a and the second lower surface 24b. When the frame body 20 is viewed transparently, the outer periphery of the second lower surface 24b surrounds the inner periphery and the outer periphery of the second upper surface 12b of the heat dissipation member 10 in the top view. The inner periphery of the second lower surface 24b surrounds the inner periphery of the second upper surface 12b of the heat dissipation member 10. The inner periphery of the second lower surface 24b is surrounded by the outer periphery of the second upper surface 12b of the heat dissipation member 10.

A second bonding region 28b is provided on the entire second lower surface 24b. The second upper surface 12b of the heat dissipation member 10 is bonded to the second lower surface 24b, more specifically, to the second bonding region 28b provided on the second lower surface 24b. With the second bonding region 28b, when the heat dissipation member 10 and the frame body 20 are bonded together via an inorganic bonding member such as a brazing material, the bonding strength can be improved. The melting point of the brazing material is higher than the melting point of the solder material. Therefore, when the brazing material is heated to bond the heat dissipation member 10 and the frame body 20 together, and subsequently the solder material is heated to bond the heat dissipation member 10 and the first submount 30a together, the possibility that the heat dissipation member 10 and the frame body 20 are disconnected due to the heat applied to the solder material can be reduced.

In the example illustrated in FIG. 1E, the second bonding region 28b is provided over the entire second lower surface 24b, but the second bonding region 28b may be provided on a portion of the second lower surface 24b. Although a bonding region is not provided on the first lower surface 24a, a bonding region may be provided on a portion of or the entire first lower surface 24a. In this case, not only the lower surface 14 of the heat dissipation member 10, but also the first lower surface 24a of the frame body 20 can be bonded to the support member of the light-emitting device 100A via an inorganic bonding member, such as a solder material, and therefore the bonding strength can be further improved.

In the example illustrated in FIG. 1F, the first lower surface 24a of the frame body 20 is located above the lower surface 14 of the heat dissipation member 10. Therefore, when the lower surface 14 of the heat dissipation member 10 is bonded to the support member of the light-emitting device 100A via an inorganic bonding member, the frame body 20 does not interfere with the bonding. Further, preventing the frame body 20 from interfering with the bonding allows for reducing a thickness of the inorganic bonding member; thus, the heat generated from the semiconductor laser element 40 during driving can be effectively transferred to the support member via the heat dissipation member 10.

Alternatively, the first lower surface 24a of the frame body 20 may be in the same plane as the lower surface 14 of the heat dissipation member 10. When the heat dissipation member 10 is bonded to the support member of the light-emitting device 100A, the first lower surface 24a of the frame body 20 may be located lower than the lower surface 14 of the heat dissipation member 10 as long as the inorganic bonding member is thick and the frame body 20 does not interfere with the bonding.

The frame body 20 may be made of a ceramic selected from the group consisting of AlN, SiN, SiC, and alumina, for example. The frame body 20 may have the dimension in the X direction in a range of, for example, 2 mm to 10 mm, the maximum dimension in the Y direction in a range of, for example, 4 mm to 20 mm, and the dimension in the Z direction in a range of, for example, 0.4 mm to 2.0 mm.

The first to fourth conductive regions 26a to 26d and the first and second bonding regions 28a and 28b may be made of, for example, at least one metal material selected from the group consisting of Ag, Cu, W, Au, Ni, Pt, Ti, and Pd. The first to fourth conductive regions 26a to 26d and the first bonding region 28a may be formed by, for example, disposing a metal film on the entire upper surface 22a and patterning the metal film by etching or plating.

### First Submount 30a

As illustrated in FIG. 1C, the first submount 30a includes a plate-shaped main body portion 30a0 extending along the XZ plane, a first upper metal film 36a1 and a second upper metal film 36a2 provided on the upper surface of the main body portion 30a0, and a lower metal film 38a provided on the lower surface of the main body portion 30a0. The first upper metal film 36a1 and the second upper metal film 36a2 are aligned along the X direction and electrically insulated from one another. The upper surface 32a of the first submount 30a corresponds to the upper surface of the first upper metal film 36a1 and the upper surface of the second upper metal film 36a2. The lower surface 34a of the first submount 30a corresponds to the lower surface of the lower metal film 38a.

The first upper metal film 36a1 and the second upper metal film 36a2 are used for power supply to the semiconductor laser element 40 and heat dissipation of the semiconductor laser element 40. The first upper metal film 36a1 is electrically connected to one of the conductive members 40w and the semiconductor laser element 40 that are illustrated in FIG. 1B. The second upper metal film 36a2 is electrically connected to the other of the conductive members 40w illustrated in FIG. 1B and the relay member 42 illustrated in FIG. 1C. With the first upper metal film 36a1, when the first submount 30a and the semiconductor laser element 40 are bonded via an inorganic bonding member such as a solder material, the bonding strength can be improved. With the second upper metal film 36a2, when the first submount 30a and the relay member 42 are bonded via a similar inorganic bonding member, the bonding strength can be improved. With the lower metal film 38a, when the first submount 30a and the heat dissipation member 10 are bonded via a similar inorganic bonding member, the bonding strength can be improved.

As illustrated in FIG. 1F, the lower surface 34a of the first submount 30a includes the first region 33a bonded to the first upper surface 12a and the second region 33b that faces the upper surface 22a of the frame body 20 and that is not bonded to the upper surface 22a of the frame body 20. The upper surface 32a of the first submount 30a has a third region 33c located on the side opposite to the second region 33b and a fourth region 33d located on the side opposite to the first region 33a.

In the present specification, the expression “the second region 33b faces the upper surface 22a of the frame body 20” means that a portion or an entirety of the second region 33b overlaps a portion or an entirety of the upper surface 22a of the frame body 20.

In the example illustrated in FIG. 1F, the second region 33b is located behind the first region 33a. Therefore, a portion of the first submount 30a located between the second region 33b and the third region 33c does not interfere with the travel of the laser light L. The second region 33b may be located, for example, on a lateral side of the first region 33a as long as the part does not interfere with the travel of the laser light L. When a direction in which the semiconductor laser element 40 extends is defined as a longitudinal direction and a direction perpendicular to the longitudinal direction is defined as a short direction in the top view, the lateral side corresponds to the short direction.

As described above, the second region 33b is located in a direction different from the emission direction of the laser light L emitted from the semiconductor laser element 40 with respect to the first region 33a. The direction different from the emission direction of the laser light L may be, for example, a direction opposite to the emission direction of the laser light L or a direction intersecting with the emission direction of the laser light L.

In a configuration in which the upper surface 32a of the first submount 30a does not include the third region 33c, not only the semiconductor laser element 40 having a relatively large amount of heat generation, but also a portion of each of the conductive members 40w having a relatively small amount of heat generation needs to be provided on the fourth region 33d. This results in reduction of the region in which the semiconductor laser element 40 is to be provided in the fourth region 33d.

In contrast, in the light-emitting device 100A according to the first embodiment, a portion of each of the conductive members 40w is located on the third region 33c in the upper surface 32a of the first submount 30a, and the semiconductor laser element 40 is preferentially provided on the fourth region 33d. The semiconductor laser element 40 is located inward of the outer perimeter of the first upper surface 12a of the heat dissipation member 10 in the top view. In other words, the semiconductor laser element 40 does not protrude outward of the first upper surface 12a of the heat dissipation member 10 in the top view. Therefore, the heat generated from the semiconductor laser element 40 can be effectively transferred to the heat dissipation member 10 via the first submount 30a. The above-described protective element and/or temperature measuring element that generate a relatively small amount of heat generation may be disposed in the third region 33c.

When the output of the laser light L emitted from the semiconductor laser element 40 is increased to be 10 W or more, the dimensions of the semiconductor laser element 40 in the X direction, the Y direction, and the Z direction is increased accordingly. If the dimensions of the heat dissipation member 10 in the X direction and the Z direction are increased to effectively transfer the heat generated from the semiconductor laser element 40 to the outside of the light-emitting device 100A, the heat dissipation member 10 and the frame body 20 may be disconnected from each other due to the thermal expansion of the heat dissipation member 10.

In contrast, in the light-emitting device 100A according to the first embodiment, a portion of each of the conductive members 40w is located on the third region 33c, so that the fourth region 33d has room for the semiconductor laser element 40 having the large dimension even when the dimensions of the heat dissipation member 10 in the X direction and the Z direction are not large,. As described above, in the light-emitting device 100A according to the first embodiment, the heat generated from the semiconductor laser element 40 can be effectively released to the outside of the light-emitting device 100A even with the semiconductor laser element 40 having the output of the laser light L of 10 W or more.

When the heat dissipation member 10 expands due to the heat generated from the semiconductor laser element 40, even if the heat dissipation member 10 and the frame body 20 are not disconnected from each other, the heat dissipation member 10 and the frame body 20 may be shifted in position. Even in this case, with the second region 33b not bonded to the upper surface 22a of the frame body 20, the load experienced on the first submount 30a and the frame body 20 can be reduced. In the example illustrated in FIG. 1F, with respect to a support surface, which supports the heat dissipation member 10 and/or the frame body 20, of the support member of the light-emitting device 100A, the height of the first upper surface 12a of the heat dissipation member 10 from the support surface is greater than the height of the upper surface 22a of the frame body 20 from the support surface. Due to the height relationship between these two upper surfaces, the second region 33b and the upper surface 22a of the frame body 20 are spaced apart from each other. Therefore, even when the heat dissipation member 10 and the frame body 20 are shifted in position due to thermal expansion of the heat dissipation member 10, the load experienced on the first submount 30a and the frame body 20 can be further reduced. In the present description, “A and B are spaced apart from each other” means that the shortest distance between A and B is 10 μm or more.

The relationship between the second region 33b of the first submount 30a and the upper surface 22a of the frame body 20 are not limited to the example illustrated in FIG. 1F, and the second region 33b of the first submount 30a and the upper surface 22a of the frame body 20 are not necessarily spaced apart from each other as long as they are not bonded to each other. As long as they are not bonded to each other, the distance between them may be less than 10 μm, or they may be in contact with one another.

### Second Submount 30b

As illustrated in FIG. 1C, the second submount 30b includes a plate-shaped main body portion 30b0 extending along the XZ plane, an upper metal film 36b disposed on the upper surface of the main body portion 30b0, and a lower metal film 38b disposed on the lower surface of the main body portion 30b0. The upper surface 32b of the second submount 30b corresponds to the upper surface of the upper metal film 36b. The lower surface 34b of the second submount 30b corresponds to the lower surface of the lower metal film 38b of the second submount 30b.

With the upper metal film 36b, when the second submount 30b and the sealing member 60A are bonded together via an inorganic bonding member such as a solder material as illustrated in FIGS. 1F and 1G, the bonding strength can be improved. The lower metal film 38b is used to supply power to the semiconductor laser element 40. Further, with the lower metal film 38b, when the second submount 30b and the semiconductor laser element 40 are bonded together via an inorganic bonding member such as a solder material, the bonding strength can be improved. Still further, with the lower metal film 38b, when the second submount 30b and the relay member 42 are bonded together via a similar inorganic bonding member, the bonding strength can be improved.

### Semiconductor Laser Element 40

The semiconductor laser element 40 is an edge-emission type semiconductor laser element and has an end surface 40e for emission as illustrated in FIG. 1C. The end surface 40e is a rectangular flat surface extending in the X direction and parallel to the XY plane. The semiconductor laser element 40 has a resonator extending along the Z direction and emits the laser light L from the end surface 40e in the +Z direction. The laser light L emitted from the semiconductor laser element 40 spreads relatively fast in the YZ plane and spreads relatively slowly in the XZ plane. The fast axis direction of the laser light L is parallel to the Y direction, and the slow axis direction is parallel to the X direction.

As illustrated in FIGS. 1F and 1G, the semiconductor laser element 40 is sealed by the heat dissipation member 10, the frame body 20, the sidewall 50A, and the sealing member 60A. This seal is preferably a hermetic seal. The effect of the hermetic seal increases as the wavelength of the laser light emitted from the semiconductor laser element 40 becomes short. This is because, in a configuration in which the emission surface of the semiconductor laser element 40 is not hermetically sealed and is in contact with the outside air, the shorter the wavelength of the laser light is, the higher the possibility that deterioration of the emission surface will progress due to dust attraction during operation.

As illustrated in FIG. 1G, the upper surface of the semiconductor laser element 40 is electrically connected to the lower surface of the lower metal film 38b of the second submount 30b. The lower surface of the lower metal film 38b of the second submount 30b is electrically connected to the upper surface of the relay member 42. The lower surface of the relay member 42 is electrically connected to the upper surface of the second upper metal film 36a2 of the first submount 30a. The upper surface of the second upper metal film 36a2 is electrically connected to the fourth conductive region 26d via the conductive member 40w illustrated in FIG. 1B.

As illustrated in FIG. 1G, the lower surface of the semiconductor laser element 40 is electrically connected to the upper surface of the first upper metal film 36a1 of the first submount 30a. The upper surface of the first upper metal film 36a1 is electrically connected to the third conductive region 26c via the conductive member 40w illustrated in FIG. 1B.

With the electrical relationship described above, by applying a voltage between the first conductive region 26a and the second conductive region 26b, power can be supplied to the semiconductor laser element 40.

The semiconductor laser element 40 can be configured to emit the violet, blue, green, or red laser light L in the visible region, or the infrared or ultraviolet laser light L in the invisible region. The light emission peak wavelength of the violet light is preferably in a range of 400 nm to 420 nm and more preferably in a range of 400 nm to 415 nm. The light emission peak wavelength of the blue light is preferably greater than 420 nm and 495 nm or less and more preferably in a range of 440 nm to 475 nm. The light emission peak wavelength of the green light is preferably greater than 495 nm and 570 nm or less and more preferably in a range of510 nm to 550 nm. The light emission peak wavelength of the red light is preferably in a range of 605 nm to 750 nm and more preferably in a range of 610 nm to 700 nm.

The semiconductor laser element 40 that emits the violet, blue, and green laser light L includes a laser diode containing a nitride semiconductor material. For example, GaN, InGaN, and AlGaN can be used as the nitride semiconductor material. Examples of the semiconductor laser element 40 that emits the red laser light L include a laser diode containing an InAlGaP-based, a GaInP-based, a GaAs-based, and an AlGaAs-based semiconductor materials.

The output of the laser light L emitted from the semiconductor laser element 40 may be, for example, 10 W or more.

### Relay Member 42 and Conductive Members 40w

The relay member 42 and the conductive member 40w are used to supply power to the semiconductor laser element 40. As illustrated in FIG. 1D, the relay member 42 has a rectangular parallelepiped shape extending along the Z direction. The dimension of the relay member 42 in the Z direction is substantially the same as the dimension of the semiconductor laser element 40 in the Z direction. As the areas of the upper surface and the lower surface of the relay member 42 increase, the electric resistance value of the relay member 42 can be reduced.

The conductive member 40w may be, for example, a wire. In the example illustrated in FIG. 1B, the number of the conductive members 40w is two, but the number may be three or more. Some of the three or more conductive members 40w may be electrically connected to the third conductive region 26c and the first upper metal film 36a1, and the other of them may be electrically connected to the fourth conductive region 26d and the second upper metal film 36a2 illustrated in FIG. 1C.

The relay member 42 and the conductive member 40w may be made of, for example, at least one metal material selected from the group consisting of Au, Ag, Cu, and Al.

### Sidewall 50A

As illustrated in FIGS. 1F and 1G, the sidewall 50A is supported by the upper surface 22a of the frame body 20, and surrounds the semiconductor laser element 40, the first submount 30a, and the second submount 30b. The sidewall 50A is configured to transmit the laser light L emitted from the semiconductor laser element 40. A portion of the sidewall 50A that transmits the laser light L may have a transmittance of 60% or more, for example, and preferably has the transmittance of 80% or more with respect to the laser light L. The remaining part of the sidewall 50A may or does not need to have such transmissivity.

As illustrated in FIG. 1B, the sidewall 50A has an upper surface 52A and a lower surface 54A. The upper surface 52A includes an upper bonding region 56A1, and the lower surface 54A includes a lower bonding region 56A2. With the upper bonding region 56A1, when the sidewall 50A and the sealing member 60A are bonded via an inorganic bonding member such as a solder material, the bonding strength can be improved. With the lower bonding region 56A2, when the sidewall 50A and the frame body 20 are bonded via a similar inorganic bonding member, the bonding strength can be improved.

The sidewall 50A may be made of at least one light-transmissive material selected from the group consisting of, for example, glass, silicon, quartz, synthetic quartz, sapphire, transparent ceramics, silicone resin, and plastic. The bonding regions 56A1 and 56A2 may be made, for example, the above-described metal materials, similar to the first to third conductive regions 26a to 26c and the first and second bonding regions 28a and 28b. The bonding regions 56A1 and 56A2 may be formed by a film forming process, such as sputtering or plating, for example.

### Sealing Member 60A

As illustrated in FIGS. 1F and 1G, the sealing member 60A is supported by the upper surface 52A of the sidewall 50A and seals a space surrounded by the sidewall 50A. The sealing member 60A is further supported by the upper surface 32b of the second submount 30b.

In the example illustrated in FIGS. 1F and 1G, with respect to the support surface that supports the heat dissipation member 10 and/or the frame body 20 among the support members of the light-emitting device 100A, the height of the upper surface 32b of the second submount 30b is greater than the height of the upper surface 52A of the sidewall 50A. When the sealing member 60A is a metal foil, the metal foil has flexibility, allowing the difference in height between the two surfaces to be absorbed.

Other than the example illustrated in FIGS. 1F and 1G, the upper surface 32b of the second submount 30b may be located at a position lower than the upper surface 52A of the sidewall 50A, or these two surfaces may be located in the same plane.

The sealing member 60A has a first part 60A1 bonded to the upper surface 52A of the sidewall 50A, a second part 60A2 bonded to the upper surface 32b of the second submount 30b, and a third part 60A3 connecting the peripheral part (the first part 60A1) and the flat plate part (the second part 60A2). The boundary between the second part 60A2 and the third part 60A3 is located outward of the outer edge of the upper surface 32b of the second submount 30b in the top view. The third part 60A3 is not in contact with the second submount 30b. Therefore, the possibility that the sealing member 60A is damaged due to contact with the corner of the second submount 30b can be reduced.

The base material of the metal foil described above may be, for example, at least one selected from the group consisting of aluminum, copper, gold, Kovar, titanium, stainless steel, tungsten, beryllium copper, titanium, nickel, silver, platinum, nichrome, tantalum, molybdenum, and niobium or an alloy thereof. The base material is preferably covered with, for example, a metal film. For example, the metal film may be made of at least one material selected from the group consisting of gold, platinum, titanium, nickel, chromium, palladium, and ruthenium. The metal film may be formed on a surface of the base material by a film forming process, such as sputtering and plating, for example. The thickness of the metal foil may be, for example, in a range of 10 μm to 300 μm.

### Heat Dissipation Block 70

As illustrated in FIGS. 1F and 1G, the heat dissipation block 70 is in thermal contact with the second submount 30b via the second part 60A2 of the sealing member 60A. The heat generated from the semiconductor laser element 40 is effectively released to the outside of the light-emitting device 100A not only via the first submount 30a and the heat dissipation member 10 in this order, but also via the second submount 30b, the sealing member 60A, and the heat dissipation block 70 in this order. In the present description, the heat dissipation block 70 is also referred to as “additional heat dissipation member.”

In the example illustrated in FIGS. 1A, 1B, 1F, and 1G, the heat dissipation block 70 has a rectangular parallelepiped shape, but may have other shape. The shape of the heat dissipation block 70 may be, for example, a circular plate shape or a spherical shape. The heat dissipation block 70 may be made of the same material as the heat dissipation member 10, for example. The heat dissipation block 70 may have the dimension in the X direction in a range of, for example, 1 mm to 10 mm, the dimension in the Y direction in a range of, for example, 4 mm to 20 mm, and the dimension in the Z direction in a range of, for example, 0.1 mm to 5 mm.

As described above, according to the first embodiment, even when the heat dissipation member 10 in the light-emitting device 100A expands due to the heat generated from the semiconductor laser element 40 during driving, with a structure in which the second region 33b of the first submount 30a is not bonded to the upper surface 22a of the frame body 20, the load experienced on the first submount 30a and the frame body 20 can be reduced. Thus, the light-emitting device 100A can be obtained in which the load experienced between the components can be reduced even when the components in the light-emitting device 100A expand due to the heat generated from the semiconductor laser element 40 during driving.

### Modified Example of First Embodiment

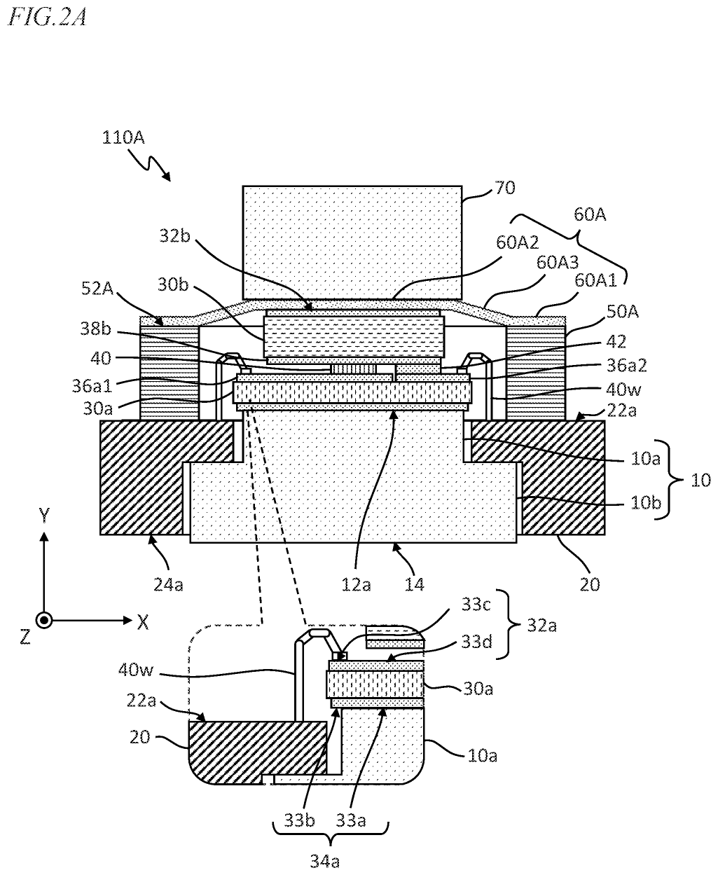

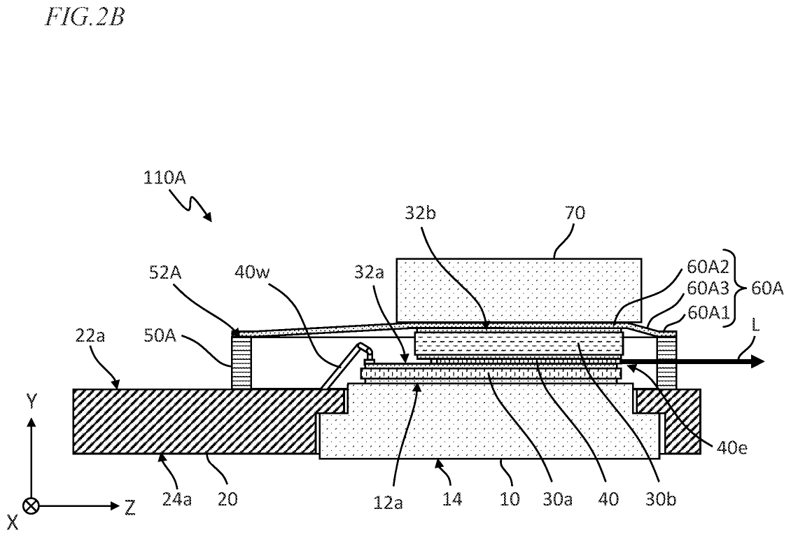

Subsequently, the modified example of the light-emitting device according to the first embodiment of the present disclosure will be described with reference to FIGS. 2A and 2B. Each of FIGS. 2A and 2B is a cross-sectional view parallel to the XY plane or the YZ plane, schematically illustrating the configuration of the modified example of the light-emitting device according to the first embodiment of the present embodiment. In a region surrounded by the broken line illustrated in FIG. 2A, the heat dissipation member 10, the frame body 20, the first submount 30a, and the peripheral configuration thereof are illustrated in an enlarged manner.

A light-emitting device 110A illustrated in FIGS. 2A and 2B differs from the light-emitting device 100A illustrated in FIGS. 1F and 1G in the shape of the first submount 30a. As illustrated in FIG. 2A, in the light-emitting device 110A, the lower surface 34a of the first submount 30a includes the first region 33a bonded to the first upper surface 12a and the second region 33b not bonded to the first upper surface 12a. The second region 33b is located on two opposite lateral sides of the first region 33a as illustrated in FIG. 2A and is not located at the rear of the first region 33a as illustrated in FIG. 2B. As illustrated in FIG. 2A, the upper surface 32a of the first submount 30a has the third region 33c located on the side opposite to the second region 33b and the fourth region 33d located on the side opposite to the first region 33a. A portion of the first submount 30a located between the second region 33b and the third region 33c does not interfere with the travel of the laser light L. Although the configuration of the end portion on the −X direction side of the first submount 30a is illustrated in the enlarged region of FIG. 2A, the end portion on the +X direction side thereof also has the same configuration.

In the light-emitting device 110A, the second region 33b overlaps with the clearance between the first flat plate part 10a of the heat dissipation member 10 and the frame body 20 in the top view, but does not face the upper surface 22a of the frame body 20. Therefore, the first submount 30a does not need to have a large dimension so much in the X direction. Even when the second region 33b does not face the upper surface 22a of the frame body 20, the portion of the first submount 30a located between the second region 33b and the third region 33c protrudes outward of the heat dissipation member 10, so that a portion of each of the conductive members 40w can be located on the third region 33c. Therefore, the semiconductor laser element 40 can be preferentially provided on the fourth region 33d. When the third region 33c is narrow, some of the conductive members 40w may be provided over the third region 33c and the fourth region 33d.

In the light-emitting device 110A, similar to the light-emitting device 100A according to the first embodiment, the second region 33b is not bonded to the upper surface 22a of the frame body 20. Therefore, the light-emitting device 110A can be obtained in which the load experienced between the components can be reduced even when the components in the light-emitting device 110A expand due to the heat generated from the semiconductor laser element 40 during driving.

### Second Embodiment

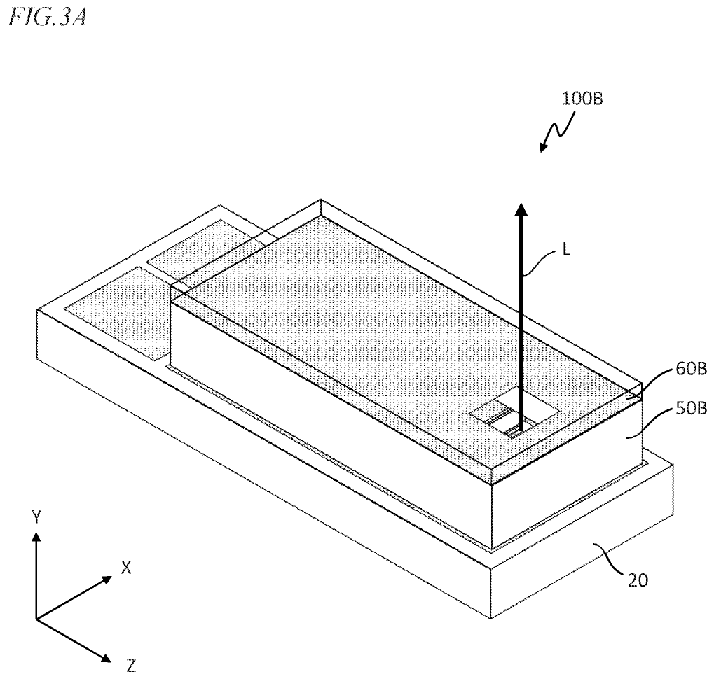

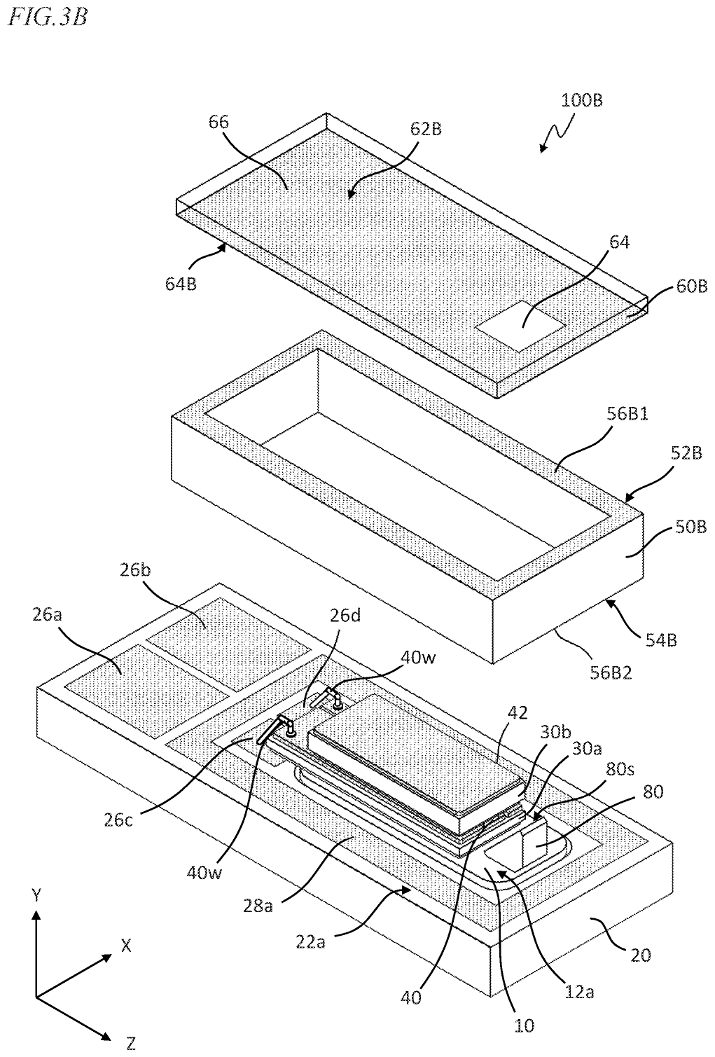

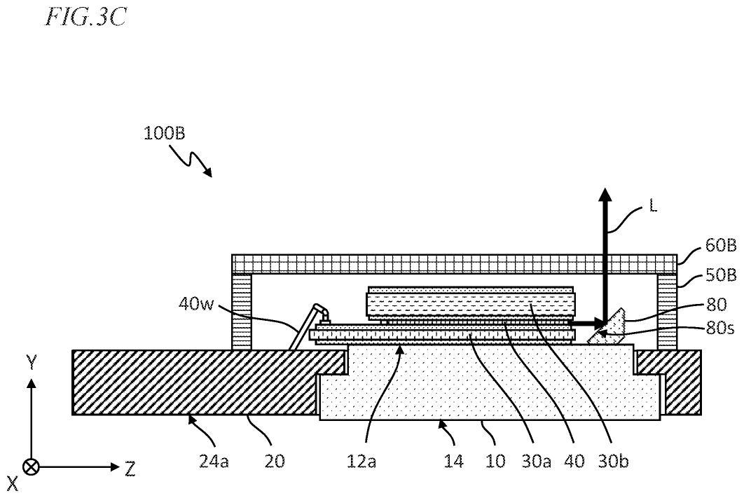

Subsequently, a configuration example of a light-emitting device according to the second embodiment of the present disclosure will be described with reference to FIGS. 3A to 3C. FIG. 3A is a perspective view schematically illustrating the configuration of the light-emitting device according to the exemplary second embodiment of the present disclosure. A light-emitting device 100B illustrated in FIG. 3A emits the laser light L upward, unlike the light-emitting device 100A illustrated in FIG. 1A. FIG. 3B is an exploded perspective view of the light-emitting device 100B illustrated in FIG. 3A. The light-emitting device 100B illustrated in FIG. 3B differs from the light-emitting device 100A illustrated in FIG. 1B in that the light-emitting device 100B includes a mirror member 80, a sidewall 50B, and a sealing member 60B instead of the sidewall 50A, the sealing member 60A, and the heat dissipation block 70. The mirror member 80 has a reflective surface 80s. FIG. 3C is a cross-sectional view parallel to a YZ plane of the light-emitting device 100B illustrated in FIG. 3A.

As illustrated in FIG. 3C, in the light-emitting device 100B according to the second embodiment, the reflective surface 80s of the mirror member 80 is configured to reflect the laser light L emitted from the semiconductor laser element 40 to change the traveling direction of the laser light to the direction away from the first upper surface 12a of the heat dissipation member 10. The sealing member 60A is configured to transmit the laser light L reflected by the reflective surface 80s.

Hereinafter, among the components of the light-emitting device 100B, the mirror member 80, the sidewall 50B, and the sealing member 60B will be described in detail.

### Mirror Member 80

As illustrated in FIG. 3C, the mirror member 80 is supported by the first upper surface 12a of the heat dissipation member 10. The mirror member 80 has a uniform cross-sectional shape in the X direction. The cross-sectional shape is substantially triangular. The mirror member 80 has a lower surface, a rear surface, and an inclined surface connecting the lower surface and the rear surface. The lower surface is parallel to the XZ plane and the back surface is parallel to the XY plane. The direction normal to the inclined surface is a direction that is parallel to the YZ plane, forms an acute angle with the +Y direction, and forms an acute angle with the −Z direction. An angle formed between the lower surface and the inclined surface of the mirror member 80 is 45°, but is not limited to this angle, and may be in a range of 30° to 60°, for example.

The mirror member 80 includes the reflective surface 80s in the above-described inclined surface. The reflective surface 80s is inclined with respect to the first upper surface 12a of the heat dissipation member 10 and faces obliquely upward. In the present description, “obliquely upward” means a direction forming an angle in a range of 30° to 60° with the +Y direction. The normal direction of the reflective surface 80s may or does not need to be parallel to the YZ plane as long as the reflective surface 80s can receive the laser light L emitted from the semiconductor laser element 40 and the normal direction of the reflective surface 80s is a direction that forms the angle in a range from 30° to 60° with the +Y direction. An angle formed between the direction in which the laser light L are away from the first upper surface 12a of the heat dissipation member 10 and the normal direction of the first upper surface 12a of the heat dissipation member 10 may be in a range of 0° to 5°, for example.

### Sidewall 50B

The sidewall 50B is supported by the upper surface 22a of the frame body 20 and surrounds the semiconductor laser element 40, similar to the sidewall 50A in the first embodiment. On the other hand, unlike the sidewall 50A, the sidewall 50B preferably does not have transmissivity of the laser light L. This is to prevent stray light other than the laser light L generated inside the light-emitting device 100B from leaking from the sidewall 50B. As illustrated in FIG. 3B, the sidewall 50B has an upper surface 52B and a lower surface 54B, the upper surface 52B includes an upper bonding region 56B1, and the lower surface 54B includes a lower bonding region 56B2. With the upper bonding region 56B1, when the sidewall 50B and the sealing member 60B are bonded via an inorganic bonding member, such as a solder material, the bonding strength can be improved. With the lower bonding region 56B2, when the sidewall 50B and the frame body 20 are bonded via a similar inorganic bonding member, the bonding strength can be improved.

The sidewall 50B may be made of, for example, a ceramic similar to that of the frame body 20 described above. The sidewall 50B may have the dimension in the X direction in a range, for example, from 1 mm to 10 mm, the maximum dimension in the Y direction in a range, for example, from 4 mm to 15 mm, and the dimension in the Z direction in a range, for example, from 0.1 mm to 2 mm.

The bonding regions 56B1 and 56B2 may be made of, for example, a metal material similar to the above-described metal material of the first to fourth conductive regions 26a to 26d and the first and second bonding regions 28a and 28b. The bonding regions 56B1 and 56B2 may be formed by a film forming process, such as sputtering and plating, for example.

### Sealing Member 60B

As illustrated in FIG. 3B, the sealing member 60B has an upper surface 62B and a lower surface 64B. The lower surface 64B of the sealing member 60B faces the first upper surface 12a of the heat dissipation member 10, and the upper surface 62B of the sealing member 60B is located on the side opposite to the lower surface 64B of the sealing member 60B. In the present specification, the expression “the lower surface 64B of the sealing member 60B faces the first upper surface 12a of the heat dissipation member 10” means that a portion or an entirety of the lower surface 64B of the sealing member 60B overlaps a portion or an entirety of the first upper surface 12a of the heat dissipation member 10 in a direction perpendicular to the first upper surface 12a of the heat dissipation member 10. The lower surface 64B of the sealing member 60B is also referred to as a “facing surface.” The sealing member 60B is located above the first submount 30a, the second submount 30b, and the semiconductor laser element 40. The sealing member 60B transmits the laser light L reflected by the reflective surface 80s.

The sealing member 60B includes, at the lower surface 64B, a light-shielding film 66 at least around a light-transmitting region 64 that transmits the laser light L. In the example illustrated in FIG. 3B, the light-transmitting region 64 has a rectangular shape, but may have other shape. The shape of the light-transmitting region 64 may be, for example, a circular shape or an elliptical shape.

Alternatively, the sealing member 60B may include, in the lower surface 64B, the light-shielding film 66 at at least a portion around the light-transmitting region 64. For example, when a part of the end of the light-transmitting region 64 coincides a part of the end of the lower surface 64B, the light-shielding film 66 may be provided at at least a part of a region described below in the lower surface 64B. The region is a region, in the lower surface 64B, adjacent to the remaining part, that is, the part other than the above-described part, of the end of the light-transmitting region 64.

The light-shielding film 66 allows for reducing the possibility that stray light other than the laser light L generated inside the light-emitting device 100B leaks to the outside of the light-emitting device 100B. The light-shielding film 66 further allows for reducing the possibility that returning light of the laser light L emitted to the outside of the light-emitting device 100B reaches the semiconductor laser element 40. When irradiation by the returning light can be reduced, the semiconductor laser element 40 is less likely to be damaged.

In the example illustrated in FIG. 3B, the light-shielding film 66 is provided over the entire region other than the light-transmitting region 64 in the lower surface 64B. The light-shielding film 66 provided in such a manner further reduces the possibility that the above-described stray light leaks to the outside of the light-emitting device 100B and the possibility that the above-described return light reaches the semiconductor laser element 40.

In the sealing member 60B, not only the light-transmitting region 64, but also a portion of the sealing member 60B that overlaps with the light-transmitting region 64 in the top view is also configured to transmit the laser light L. The portion of the sealing member 60B that transmits the laser light L may have a transmittance of 60% or more, for example, and preferably has the transmittance of 80% or more with respect to the laser light L. The remaining part of the sealing member 60B may or does not need to have such transmissivity.

The sealing member 60B may be made of, for example, a light-transmissive material similar to the above-described light-transmissive material of the sidewall 50A in the first embodiment. The sealing member 60B may have the dimension in the X direction in a range of, for example, 1 mm to 10 mm, the dimension in the Y direction in a range of, for example, 4 mm to 15 mm, and the dimension in the Z direction in a range of, for example, 0.1 mm to 0.5 mm.

The light-shielding film 66 may be made of, for example, a metal material similar to the above-described metal material of the first to fourth conductive regions 26a to 26d and the first and second bonding regions 28a and 28b. The light-shielding film 66 may be formed by, for example, providing a metal film on the entire lower surface 64B of the sealing member 60B and patterning the metal film by etching or plating, for example, similarly to the first to fourth conductive regions 26a to 26d and the first bonding region 28a.

The peripheral region of the light-shielding film 66 is bonded to the upper bonding region 56B1 provided on the upper surface 52B of the sidewall 50B via an inorganic bonding member, such as a solder material. When the light-shielding film 66 is made of the above-described metal material, the light-shielding film 66 allows for improving the bonding strength when the sealing member 60B and the sidewall 50B are bonded via the inorganic bonding member.

Similar to the first embodiment, according to the second embodiment, the light-emitting device 100B can be obtained in which, even when the components in the light-emitting device 100B expand due to the heat generated from the semiconductor laser element 40 during driving, a load experienced between the components can be reduced. Further, according to the second embodiment, unlike the first embodiment, the laser light L emitted from the semiconductor laser element 40 is reflected by the reflective surface 80s of the mirror member 80, thus ensuring emitting the laser light L upward.

The first submount 30a included in the light-emitting device 110A illustrated in FIGS. 2A and 2B may be used instead of the first submount 30a included in the light-emitting device 100B according to the second embodiment.

In the present description, the sidewall 50A and the sealing member 60A in the first embodiment are also referred to as a “cap.” The same applies to the sidewall 50B and the sealing member 60B in the second embodiment. The cap is supported by the upper surface 22a of the frame body 20, and seals the first submount 30a, the second submount 30b, and the semiconductor laser element 40.

### High-Power Laser Apparatus

The light-emitting device 100A according to the first embodiment or the light-emitting device 100B according to the second embodiment can be used for, for example, the high-power laser device. Hereinafter, the light-emitting device 100A according to the first embodiment will be described as an example, but the light-emitting device 100B according to the second embodiment may be used.

The high-power laser device includes a plurality of the light-emitting devices 100A disposed on a heat sink along one direction and a condensing lens configured to condense a plurality of the laser lights L each being the laser light L emitted from a respective one of the plurality of light-emitting devices 100A. The high-power laser device is configured to emit coupled light in which the plurality of laser light L from the condenser lens is coupled. The larger the number of the light-emitting devices 100A, the larger the number of the laser light L, and thus the greater the output of the coupled light can be.

The present disclosure includes light emitting devices according to the following aspects.

### Aspect 1

A light-emitting device, comprising: a heat dissipation member having a mounting surface; a frame body fixed to the heat dissipation member and having an upper surface; a submount supported by the mounting surface and having an upper surface and a lower surface; and a semiconductor laser element supported by the upper surface of the submount, wherein the lower surface of the submount includes a first region bonded to the mounting surface and a second region facing the upper surface of the frame body and not bonded to the upper surface of the frame body.

### Aspect 2

The light-emitting device according to aspect 1, wherein the frame body surrounds the heat dissipation member, and the upper surface of the frame body is located outward of the mounting surface when viewed along a direction normal to the mounting surface.

### Aspect 3

The light-emitting device according to aspect 1 or 2, wherein the second region of the lower surface of the submount and the upper surface of the frame body are spaced apart from each other.

### Aspect 4

The light-emitting device according to any one of aspects 1 to 3, wherein a height of the mounting surface of the heat dissipation member is greater than a height of the upper surface of the frame body with respect to a support surface that supports the heat dissipation member and/or the frame body.

### Aspect 5

The light-emitting device according to any one of aspects 1 to 4, wherein the semiconductor laser element is located inward of the outer perimeter of the mounting surface when viewed along a direction perpendicular to the mounting surface of the heat dissipation member.

### Aspect 6

The light-emitting device according to any one of aspects 1 to 5, wherein the upper surface of the submount has a third region located on a side opposite to the second region, the light-emitting device further comprises a conductive member electrically connected to the semiconductor laser element, and a portion of the conductive member is located on the third region.

### Aspect 7

The light-emitting device according to aspect 6, wherein the submount comprises a main body portion and a metal film disposed on the main body portion, and the metal film is electrically connected to the conductive member and the semiconductor laser element.

### Aspect 8

The light-emitting device according to any one of aspects 1 to 7, wherein the second region is located in a direction different from an emission direction of laser light emitted from the semiconductor laser element with respect to the first region.

### Aspect 9

The light-emitting device according to any one of aspects 1 to 8, wherein an absolute value of a difference between a thermal expansion coefficient of the heat dissipation member and a thermal expansion coefficient of the frame body is in a range of 1.0×10⁻⁶K⁻¹ to 5.0×10⁻⁵K⁻¹.

### Aspect 10

The light-emitting device according to aspect 9, wherein the heat dissipation member is located inside a square having one side of 7 mm in a top view.

### Aspect 11

The light-emitting device according to any one of aspects 1 to 10, wherein the heat dissipation member has a thermal conductivity in a range of 10 W/m·K to 2000 W/m·K.

### Aspect 12

The light-emitting device according to any one of aspects 1 to 11, wherein an output of laser light emitted from the semiconductor laser element is 10 W or more.

### Aspect 13

The light-emitting device according to any one of aspects 1 to 12 further includes a cap that is supported by the upper surface of the frame body and seals the semiconductor laser element and the submount.

### Aspect 14

In the light-emitting device according to aspect 13, the cap further includes a sidewall and a sealing member. The sidewall is supported by the upper surface of the frame body, surrounds the semiconductor laser element and the submount, and has an upper surface. The sealing member is supported by the upper surface of the sidewall and seals a space surrounded by the sidewall.

### Aspect 15

In the light-emitting device according to aspect 14, the semiconductor laser element has an upper surface and includes an additional submount supported by the upper surface of the semiconductor laser device and having an upper surface, and the sealing member is supported by the upper surface of the sidewall and the upper surface of the additional submount.

### Aspect 16

In the light-emitting device according to aspect 15, the sealing member is a metal foil.

### Aspect 17

In the light-emitting device according to aspect 15 or 16, the sealing member has an upper surface, and further includes an additional heat dissipation member supported by the upper surface of the sealing member.

### Aspect 18

In the light-emitting device according to any one of aspects 15 to 17, the sidewall transmits laser light emitted from the semiconductor laser element.

### Aspect 19

In the light-emitting device according to aspect 18, the laser light has a wavelength in a range from 420 nm to 450 nm.

### Aspect 20

A light-emitting device comprising: heat dissipation member having a first upper surface and a second upper surface located below the first upper surface; a frame body having a first lower surface and a second lower surface that is located above the first lower surface and is bonded to the second upper surface of the heat dissipation member; a submount supported by the first upper surface and having an upper surface and a lower surface; and a semiconductor laser element supported by the upper surface of the submount, wherein the lower surface of the submount includes a first region bonded to the first upper surface and a second region not bonded to the first upper surface.

### Aspect 21

The light-emitting device according to aspect 20, wherein the second region does not face the upper surface of the frame body.

### Aspect 22

The light-emitting device according to aspect 20 or 21, wherein the second region is located on two opposite lateral sides of the first region.

### Aspect 23

The light-emitting device according to any one of aspects 20 to 22, wherein the upper surface of the submount has a third region located on a side opposite to the second region, the light-emitting device further comprises a conductive member electrically connected to the semiconductor laser element, and a portion of the conductive member is located on the third region.

The light-emitting device according to the present disclosure may be used for, for example, industrial fields requiring a high-power laser light source, such as cutting, drilling, local heat treatment, surface treatment, metal welding, and 3D printing of various materials.

What is claimed is:

1. A light-emitting device comprising:
a heat dissipation member having a mounting surface;
a frame body fixed to the heat dissipation member and having an upper surface;
a submount supported by the mounting surface and having an upper surface and a lower surface; and
a semiconductor laser element supported by the upper surface of the submount, wherein:
the lower surface of the submount includes:
a first region bonded to the mounting surface, and
a second region facing the upper surface of the frame body and not bonded to the upper surface of the frame body.

2. The light-emitting device according to claim 1, wherein:
the frame body surrounds the heat dissipation member, and
the upper surface of the frame body is located outward of the mounting surface when viewed along a direction normal to the mounting surface.

3. The light-emitting device according to claim 1, wherein:
the second region of the lower surface of the submount and the upper surface of the frame body are spaced apart from each other.

4. The light-emitting device according to claim 1, wherein:
a height of the mounting surface of the heat dissipation member is greater than a height of the upper surface of the frame body, with respect to a support surface that supports the heat dissipation member and/or the frame body.

5. The light-emitting device according to claim 1, wherein:
the semiconductor laser element is located inward of the outer perimeter of the mounting surface when viewed along a direction perpendicular to the mounting surface of the heat dissipation member.

6. The light-emitting device according to claim 1, wherein:
the upper surface of the submount has a third region located on a side opposite to the second region,
the light-emitting device further comprises a conductive member electrically connected to the semiconductor laser element, and
a portion of the conductive member is located on the third region.

7. The light-emitting device according to claim 6, wherein:
the submount comprises a main body portion, and a metal film disposed on the main body portion, and
the metal film is electrically connected to the conductive member and the semiconductor laser element.

8. The light-emitting device according to claim 1, wherein:
the second region is located in a direction different from an emission direction of laser light emitted from the semiconductor laser element with respect to the first region.

9. The light-emitting device according to claim 1, wherein:
an absolute value of a difference between a thermal expansion coefficient of the heat dissipation member and a thermal expansion coefficient of the frame body is in a range of 1.0×10⁻⁶K⁻¹ to 5.0×10⁻⁵K⁻¹.

10. The light-emitting device according to claim 9, wherein:
the heat dissipation member is located inside a square having one side of 7 mm in a top view.

11. The light-emitting device according to claim 1, wherein:
the heat dissipation member has a thermal conductivity in a range of 10 W/m·K to 2000 W/m·K.

12. The light-emitting device according to claim 1, wherein:
an output of laser light emitted from the semiconductor laser element is 10W or more.

13. A light-emitting device comprising:
a heat dissipation member having a first upper surface, and a second upper surface located below the first upper surface;
a frame body having a first lower surface, and a second lower surface that is located above the first lower surface and is bonded to the second upper surface of the heat dissipation member;
a submount supported by the first upper surface and having an upper surface and a lower surface; and
a semiconductor laser element supported by the upper surface of the submount, wherein:
the lower surface of the submount includes:
a first region bonded to the first upper surface, and
a second region not bonded to the first upper surface.

14. The light-emitting device according to claim 13, wherein:
the second region does not face the upper surface of the frame body.

15. The light-emitting device according to claim 13, wherein:
the second region is located on two opposite lateral sides of the first region.

16. The light-emitting device according to claim 13, wherein:
the upper surface of the submount has a third region located on a side opposite to the second region,
the light-emitting device further comprises a conductive member electrically connected to the semiconductor laser element, and
a portion of the conductive member is located on the third region.
